(19) United States
(12) Patent Application Publication
(10) Pub. No.: US 2026/0121320 A1
(43) Pub. Date: Apr. 30, 2026

(54) BOARD CASE, CARD EDGE BOARD DEVICE, AND CARD EDGE CONNECTION STRUCTURE

(71) Applicant: HIROSE ELECTRIC CO., LTD., Kanagawa (JP)

(72) Inventors: Akira NAGAMINE, Kanagawa (JP); Isao TASHIRO, Kanagawa (JP)

(21) Appl. No.: 19/361,538

(22) Filed: Oct. 17, 2025

(30) Foreign Application Priority Data
Oct. 30, 2024 (JP) 2024-190350

(51) Int. Cl. H01R 12/72; H01R 12/75; H01R 13/639; H05K 5/00

(52) U.S. Cl. CPC H01R 12/721; H01R 12/75; H01R 13/639; H05K 5/0039; H05K 5/0069

(57) ABSTRACT

Provided is a board case including: a case body that houses a board body; and a fitting tubular body, wherein the case body is formed dividable into a first and a second divided case, the fitting tubular body is formed dividable into a first and a second divided tubular portion, the first divided case includes one surface having a board passing opening, the board passing opening is formed such that the board body is able to pass through the board passing opening in a posture of a principal surface being parallel to the one surface or a posture of the principal surface being perpendicular to the one surface, the first divided tubular portion includes a contact passing opening, the contact passing opening is formed such that a contact is able to pass through the contact passing opening along with passage of the board body through the board passing opening.

### CROSS-REFERENCE TO RELATED APPLICATION

This application claims priority from Japanese Patent Application No. 2024-190350 filed with the Japan Patent Office on October 30, 2024, the entire content of which is hereby incorporated by reference.

### BACKGROUND

### 1. Technical Field

The present disclosure relates to a board case, a card edge board device, and a card edge connection structure.

### 2. Related Art

There has been known a case housing a board having a contact at an end portion (for example, see JP-A-2017-117914). The case of JP-A-2017-117914 includes a first housing portion opened in the upper surface, a tubular second housing portion opened in the side surface, and a tubular communication portion causing both these housing portions to communicate with each other. In a case where the board is housed in the case, an elastic member is attached to the board, and the end portion (contact) of the board enters the communication portion in a state of the board being in an inclined posture. At this time, while the elastic member is contacting an abutting portion provided at the communication portion, the contact enters the second housing portion. Thereafter, the posture of the board is deformed to a horizontal posture, and in this manner, the board is housed in the first housing portion.

### SUMMARY

A board case according to the present disclosure is a board case for housing a card edge board having a contact at an end portion of a board body, the board case including: a case body forming a housing space in which the board body is housable; and a fitting tubular body forming a fitting space in which the contact of the card edge board is housable and a card edge connector connected to the card edge board is fittable, in which the fitting tubular body is formed in a tubular shape having an opening opened along a direction parallel to a principal surface of the card edge board housed in the board case and extending outward of an inside of the housing space, the case body is formed dividable into a first divided case and a second divided case, the fitting tubular body is formed dividable into a first divided tubular portion formed integrally with the first divided case and a second divided tubular portion formed integrally with the second divided case, the first divided case is formed in a box shape including one surface having a board passing opening, the board passing opening is formed such that when the card edge board is housed in the board case, the board body is able to pass through the board passing opening in a posture of the principal surface being parallel to the one surface or a posture of the principal surface being perpendicular to the one surface, and the board body is supported by the first divided case while maintaining any one of the postures at a time of passage through the board passing opening, the second divided case is disposed with the board body being sandwiched between the second divided case and the first divided case, and closes the board passing opening, the first divided tubular portion is formed in a box shape having a contact passing opening continuous to the board passing opening, the contact passing opening is formed such that the contact is able to pass through the contact passing opening along with passage of the board body through the board passing opening, and the contact is supported by the first divided tubular portion while maintaining a posture at a time of passage through the contact passing opening, and the second divided tubular portion is disposed with the contact being sandwiched between the second divided tubular portion and the first divided tubular portion, and closes the contact passing opening.

### BRIEF DESCRIPTION OF THE DRAWINGS

FIG. 1 is a perspective view showing a card edge connection structure according to a first embodiment of the present disclosure;

FIG. 2 is a perspective view showing the card edge connection structure according to the first embodiment of the present disclosure in a state of a card edge connector being connected to a card edge board device;

FIG. 3 is an exploded perspective view showing the card edge board device according to the first embodiment of the present disclosure;

FIG. 4 is an exploded sectional view showing the card edge board device according to the first embodiment of the present disclosure;

FIG. 5 is a perspective view showing a second divided case and a second divided tubular portion of a board case according to the first embodiment of the present disclosure;

FIG. 6 is a sectional view showing the card edge board device according to the first embodiment of the present disclosure;

FIG. 7 is an exploded perspective view showing a card edge connector of the card edge connection structure according to the first embodiment of the present disclosure;

FIG. 8 is a perspective view showing the card edge connector of the card edge connection structure according to the first embodiment of the present disclosure;

FIG. 9 is a sectional view showing the card edge connection structure (before connection) according to the first embodiment of the present disclosure;

FIG. 10 is a sectional view showing the card edge connection structure (after connection) according to the first embodiment of the present disclosure;

FIG. 11A is a perspective view showing a card edge connector of a card edge connection structure according to a modification of the first embodiment of the present disclosure;

FIG. 11B is a perspective view showing a card edge board of a card edge board device according to the modification of the first embodiment of the present disclosure;

FIG. 12 is a sectional view showing a card edge connection structure (before connection) according to a second embodiment of the present disclosure; and

FIG. 13 is an exploded perspective view schematically showing a card edge board device of a card edge connection structure according to a third embodiment of the present disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

However, in the case of JP-A-2017-117914 described above, after the board has diagonally entered the communication portion and the second housing portion, the posture of the board needs to be deformed, and for this reason, there is a problem that it is difficult to house the board in the case.

In view of the above-described situation, one object of the present disclosure is to provide a board case, a card edge board device, and a card edge connection structure capable of easily housing a card edge board.

(1) A board case according to the present disclosure is a board case for housing a card edge board having a contact at an end portion of a board body, the board case including: a case body forming a housing space in which the board body is housable; and a fitting tubular body forming a fitting space in which the contact of the card edge board is housable and a card edge connector connected to the card edge board is fittable, in which the fitting tubular body is formed in a tubular shape having an opening opened along a direction parallel to a principal surface of the card edge board housed in the board case and extending outward of an inside of the housing space, the case body is formed dividable into a first divided case and a second divided case, the fitting tubular body is formed dividable into a first divided tubular portion formed integrally with the first divided case and a second divided tubular portion formed integrally with the second divided case, the first divided case is formed in a box shape including one surface having a board passing opening, the board passing opening is formed such that when the card edge board is housed in the board case, the board body is able to pass through the board passing opening in a posture of the principal surface being parallel to the one surface or a posture of the principal surface being perpendicular to the one surface, and the board body is supported by the first divided case while maintaining any one of the postures at a time of passage through the board passing opening, the second divided case is disposed with the board body being sandwiched between the second divided case and the first divided case, and closes the board passing opening, the first divided tubular portion is formed in a box shape having a contact passing opening continuous to the board passing opening, the contact passing opening is formed such that the contact is able to pass through the contact passing opening along with passage of the board body through the board passing opening, and the contact is supported by the first divided tubular portion while maintaining a posture at a time of passage through the contact passing opening, and the second divided tubular portion is disposed with the contact being sandwiched between the second divided tubular portion and the first divided tubular portion, and closes the contact passing opening.

In the disclosure of (1), the case body is dividable into the first divided case and the second divided case, the fitting tubular body is dividable into the first divided tubular portion and the second divided tubular portion, the first divided case and the first divided tubular portion are integrally formed, and the second divided case and the second divided tubular portion are integrally formed. Moreover, the board passing opening is opened in the one surface of the first divided case. The board passing opening is formed such that when the card edge board is housed in the board case, the board body is able to pass through the board passing opening in the posture of the principal surface being parallel to the one surface having the board passing opening or the posture of the principal surface being perpendicular to the one surface. The board body enters the first divided case through the board passing opening in the posture parallel or perpendicular to the one surface of the first divided case having the board passing opening, and is supported (housed) by the first divided case while maintaining the posture at the time of passage through the board passing opening.

In the first divided tubular portion, the contact passing opening continuous to the board passing opening is opened. The contact passing opening is formed such that the contact is able to pass through the contact passing opening along with passage of the board body through the board passing opening. The board body passes through the board passing opening, and therefore, the contact is disposed in the fitting space of the fitting tubular body through the contact passing opening. That is, the contact of the board body enters the first divided tubular portion through the contact passing opening along with passage of the board body through the board passing opening, and is supported (housed) by the first divided tubular portion while maintaining the posture at the time of passage through the contact passing opening.

According to this configuration, while the card edge board (board body and contact) is maintained in the posture parallel or perpendicular to the one surface of the first divided case having the board passing opening, the card edge board can be housed in the first divided case and the first divided tubular portion. With this configuration, when the card edge board is housed in the board case, it is not necessary to incline the card edge board or change the posture thereof, and the card edge board can be easily housed in the board case. Moreover, although various electronic components are mounted on the principal surface of the board body, the card edge board (board body) is housed in the first divided case while being maintained in the posture parallel or perpendicular to the one surface of the first divided case having the board passing opening, and therefore, in a housing process, contact of the electronic components with the first divided case is reduced. With the above-described configuration, a process of incorporating the card edge board into the board case can be easily mechanized (automated), and therefore, a cost for a process of housing the card edge board in the board case can be reduced.

(2) It is preferred that the fitting tubular body has a partition structure dividing the housing space and the fitting space from each other, and the partition structure is configured to contact both front and back surfaces of the board body.

(3) It is preferred that the fitting tubular body has a partition structure dividing the housing space and the fitting space from each other, and the partition structure is configured to contact the principal surface of the board body on a first divided tubular portion side and an end surface of the board body facing the opening of the fitting tubular body.

According to the board case of (2) or (3), the partition structure can divide the housing space and the fitting space from each other, and therefore, entrance of a foreign substance into the housing space (inside the case body) from the fitting space can be reduced. Thus, the card edge board (electronic components mounted on the board body) can be protected from the foreign substance.

(4) A card edge board device according to the present disclosure includes: the board case according to any one of (1) to (3); and the card edge board housed in the board case.

(5) A card edge connection structure according to the present disclosure includes: the card edge board device according to (4); and the card edge connector connected to the card edge board.

According to the card edge board device of (4) and the card edge connection structure of (5), effects similar to those of the disclosure of (1), such as an effect of easily housing the card edge board in the board case, can be obtained.

In a case where an electronic board device such as the card edge board device is manufactured, a partner housing in which the card edge connector is to be fitted may be disposed on the board body so as to surround the contact, and may be fixed to the board body by soldering or the like. In this case, the partner housing needs to be prepared and soldered, which takes extra time and effort for manufacturing the electronic board device and increases a manufacturing cost. On the other hand, in the card edge board device according to (4) and the card edge connection structure according to (5), the first divided tubular portion and the second divided tubular portion are combined to form the fitting tubular body, and the fitting tubular body functions as a quasi-partner housing which houses the contact. According to this configuration, a process of fixing the partner housing to the board body can be omitted, and therefore, the card edge board device can be easily manufactured at a low cost.

(6) In the card edge connection structure according to the present disclosure, it is preferred that the card edge board has the contact on both front and back surfaces of the end portion of the board body, the card edge connector has a housing including a pair of contact housing portions and a board entrance groove, and a plurality of terminals, the board entrance groove is configured such that when the card edge connector is fitted in the fitting tubular body, the end portion of the board body enters the board entrance groove, and the pair of contact housing portions faces each other with the board entrance groove therebetween, the plurality of terminals is housed in the housing, sandwiches the end portion having entered the board entrance groove, and contacts the contact provided on the both front and back surfaces of the end portion of the board body, the housing has a rib bridged between the pair of contact housing portions, and the end portion of the board body is formed with a cutout in which the rib is fitted when the card edge connector is fitted in the fitting tubular body.

According to the card edge connection structure of (6), the rib couples the pair of contact housing portions. Thus, separation or approaching of the pair of contact housing portions can be reduced, and the pair of contact housing portions can be maintained with a predetermined interval. With this configuration, the internal between the plurality of terminals housed in the pair of contact housing portions is also constant, and therefore, the terminals can contact the contact on both front and back surfaces of the card edge board with proper pressure. When the card edge connector is fitted in the fitting tubular body, the rib is fitted in the cutout, and therefore, vibration of the card edge connector along the direction parallel to the principal surface of the card edge board can be reduced. Since the pair of contact housing portions is coupled by the rib, the stiffness of the entirety of the housing is improved, and therefore, vibration of the card edge connector along the direction perpendicular to the principal surface of the card edge board in a state of the end portion (contact) of the card edge board being sandwiched by the board entrance groove can also be reduced.

According to the present disclosure, the card edge board can be easily housed in the board case.

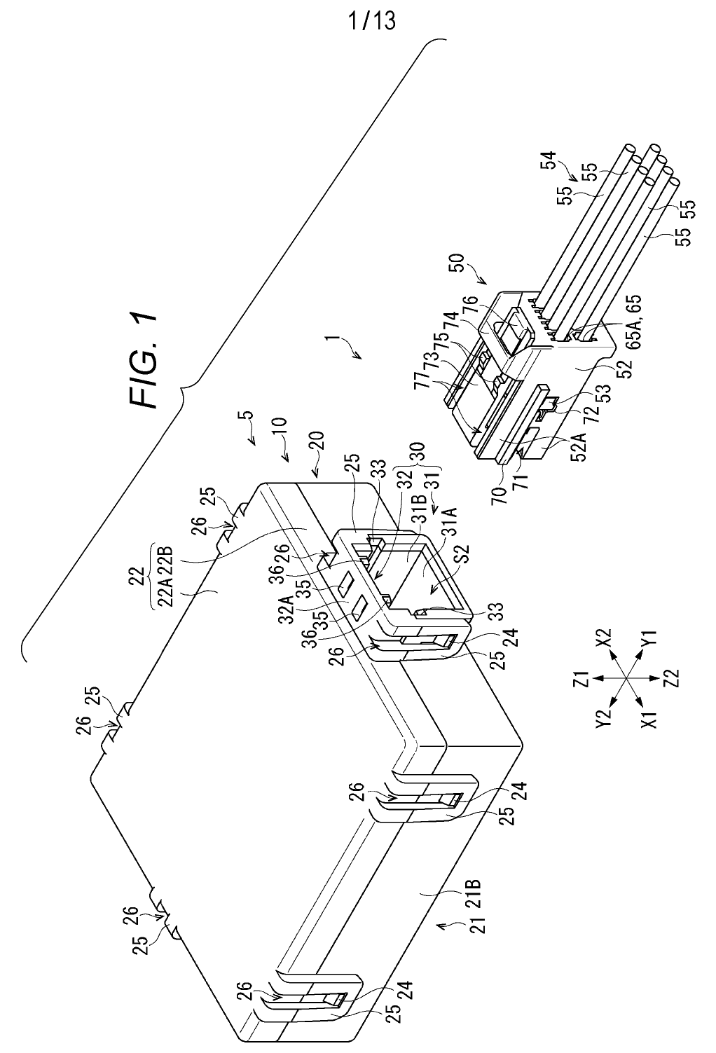

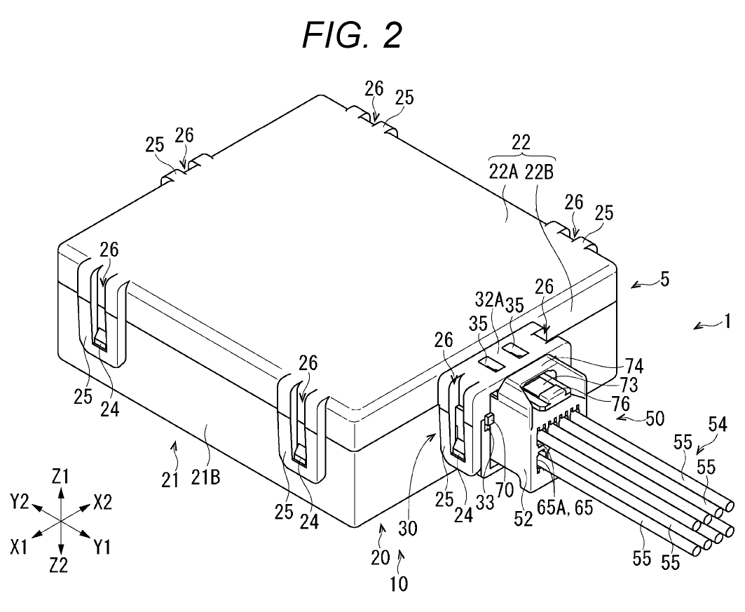

Hereinafter, embodiments of the present disclosure will be described with reference to the attached drawings. Note that X1, X2, Y1, Y2, Z1, and Z2 shown in each figure indicate the left, the right, the front, the rear, the up, and the down, respectively. Moreover, in the following description, the “front” is the Y1 side, and the “rear” is the Y2 side. Further, the “front-rear direction”, the “up-down direction”, and the “left-right direction” are perpendicular to each other. In the following description, the left-right direction may be referred to as an X1X2 direction, the front-rear direction may be referred to as a Y1Y2 direction, and the up-down direction may be referred to as a Z1Z2 direction. Terms used to indicate directions and positions in the following description are used for the sake of convenience in description, and do not limit the technical scope of the present disclosure.

[First Embodiment: Card Edge Connection Structure] With reference to FIGS. 1 and 2, a card edge connection structure 1 according to a first embodiment will be described. FIGS. 1 and 2 are perspective views showing the card edge connection structure 1.

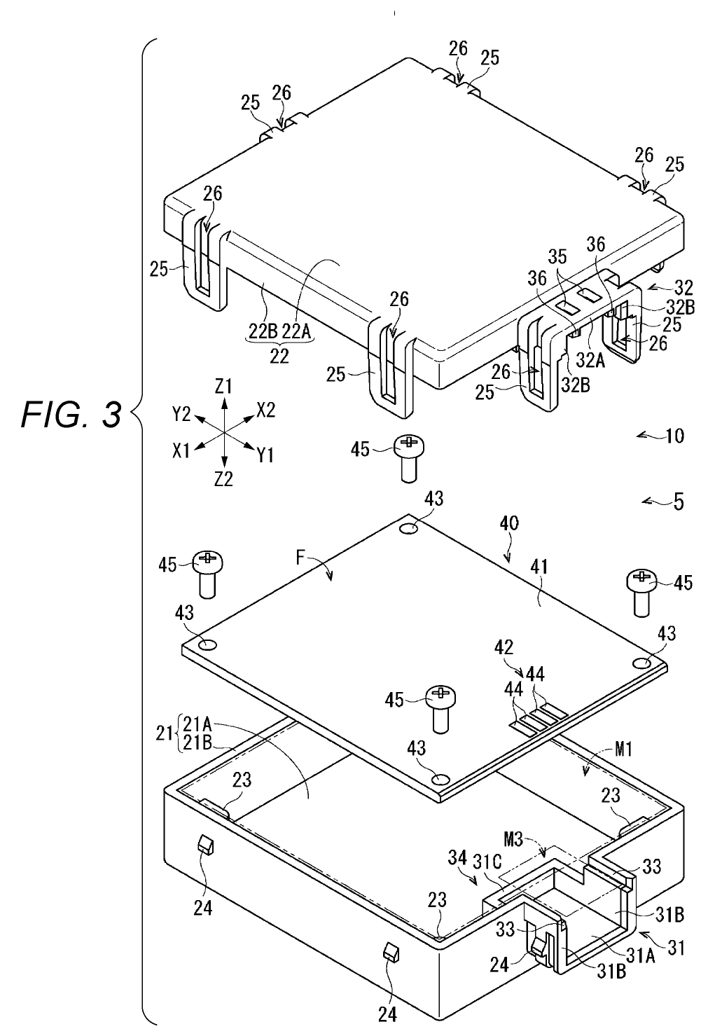

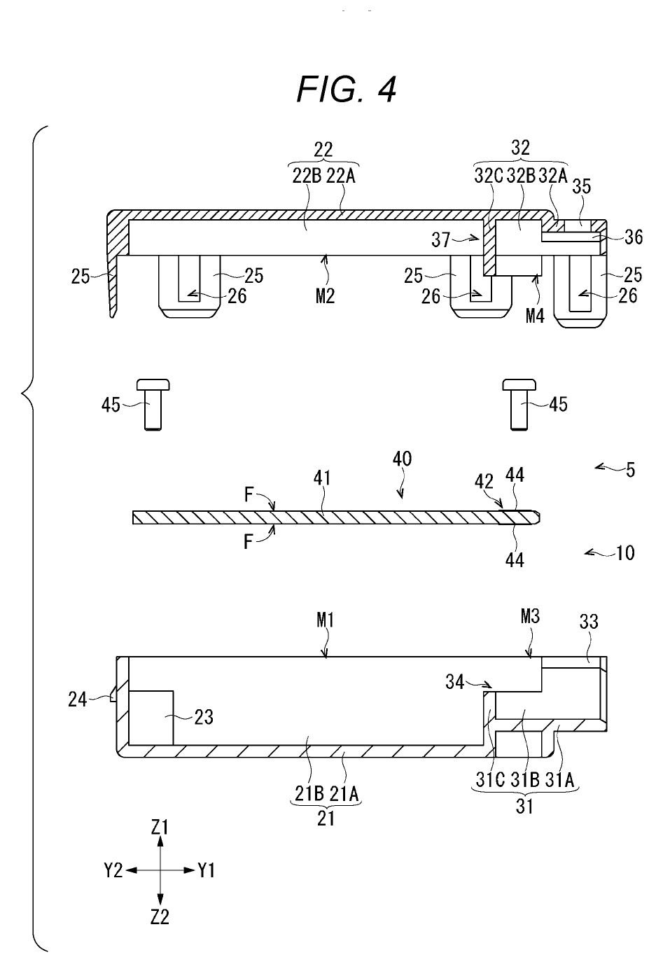

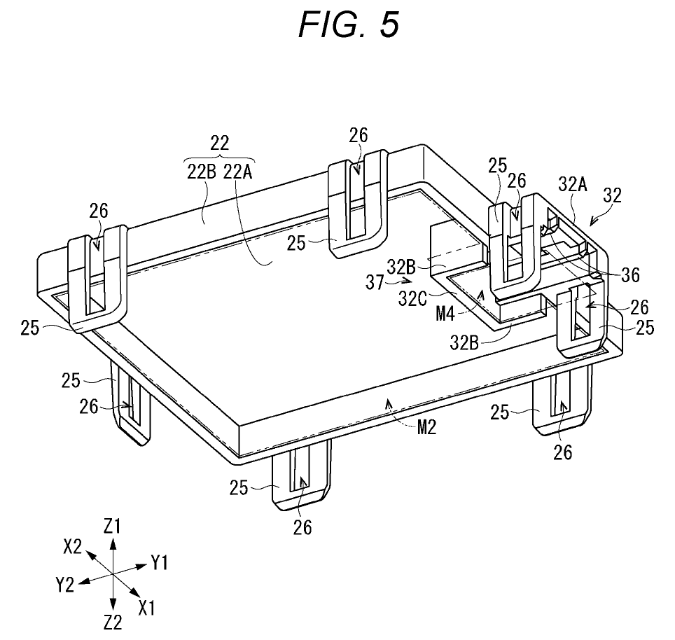

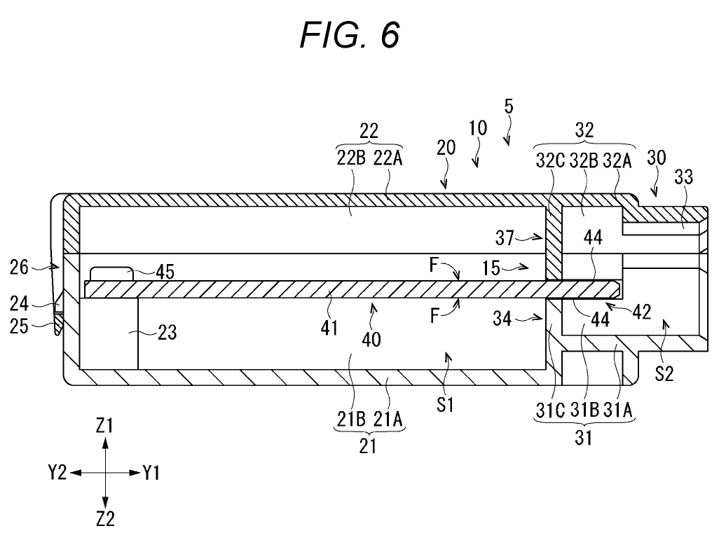

The card edge connection structure 1 includes a card edge board device 5 and a card edge connector 50. The card edge board device 5 is, for example, an electronic control unit (ECU) mounted on an automobile. The card edge board device 5 includes a board case 10 forming an exterior, and a card edge board 40 (see FIG. 3 described later) housed in the board case 10. The card edge connector 50 is attached to a tip end portion of a wire harness 54 extending from a control target (not shown). The card edge connector 50 is fitted in a fitting tubular body 30 of the board case 10, and is connected to the card edge board 40 housed in the board case 10.

[Board Case] With reference to FIGS. 3 to 6, the board case 10 will be described. FIG. 3 is an exploded perspective view showing the card edge board device 5. FIG. 4 is an exploded sectional view showing the card edge board device 5. FIG. 5 is a perspective view showing a second divided case 22 and a second divided tubular portion 32 of the board case 10. FIG. 6 is a sectional view showing the card edge board device 5.

The board case 10 is a container housing the card edge board 40 (see FIGS. 3 and 4). The board case 10 is made of, for example, metal or synthetic resin. The board case 10 includes a case body 20 and the fitting tubular body 30 (see FIGS. 1 and 2). The case body 20 is formed in a rectangular parallelepiped shape with a small height, and has therein a housing space S1 (see FIG. 6) in which the card edge board 40 (board body 41) can be housed. The fitting tubular body 30 is formed in a rectangular tubular shape narrower in the left-right direction than the case body 20 and protruding forward of the case body 20. The fitting tubular body 30 forms a fitting space S2 (see FIG. 6) in which the card edge connector 50 is fittable.

As shown in FIGS. 3 and 4, the board case 10 (case body 20 and fitting tubular body 30) is dividable in the up-down direction, for example. Specifically, the case body 20 is dividable into a first divided case 21 and the second divided case 22. The fitting tubular body 30 is dividable into a first divided tubular portion 31 and the second divided tubular portion 32. The first divided tubular portion 31 is formed integrally with the first divided case 21, and the second divided tubular portion 32 is formed integrally with the second divided case 22.

### First Divided Case

The first divided case 21 is formed in a box shape including one surface with a board passing opening M1. In the present embodiment, the board passing opening M1 is provided in the upper surface of the first divided case 21 (see FIGS. 3 and 4).

Specifically, the first divided case 21 is formed in such a deep tray shape that a rectangular peripheral wall 21B stands on a peripheral edge portion of a bottom wall 21A. The bottom wall 21A is formed in a rectangular flat plate shape. The rectangular peripheral wall 21B is formed in a rectangular tubular shape, and extends upward of the peripheral edge portion of the bottom wall 21A. As indicated by a dash-dot-dot line (virtual line) in FIG. 3, the board passing opening M1 is a quadrangular opening defined by the upper edge of the rectangular peripheral wall 21B, and in plan view, the entirety of the bottom wall 21A is exposed therethrough. Note that the upper surface of the first divided case 21 may be taken as the upper surface of the first divided case 21 in a case where it is assumed that there is no board passing opening M1.

Board fixing portions 23 are provided at four corner portions of the first divided case 21, respectively. The four board fixing portions 23 protrude upward of the bottom wall 21A (FIG. 3 and the like show only some of the four board fixing portions 23). Each board fixing portion 23 is formed in a rectangular parallelepiped shape, and the upper surface thereof is formed with an internal threaded hole (not shown). The upper surface of each board fixing portion 23 is located higher than the center of the rectangular peripheral wall 21B in the up-down direction (Z1Z2 direction).

Two pairs of engagement claws 24 (four engagement claws 24) are provided apart from each other in the front-rear direction on both left and right side surfaces (outer surfaces) of the rectangular peripheral wall 21B of the first divided case 21 (see FIG. 3). Moreover, one engagement claw 24 is provided on the outer surface of the rectangular peripheral wall 21B (see FIG. 4). Each engagement claw 24 protrudes outward of the outer surface of the rectangular peripheral wall 21B, and is formed in a block shape having a surface inclined downwardly in a protrusion direction from the top.

### Second Divided Case

As shown in FIGS. 3 to 5, the second divided case 22 is formed in a box shape having a board opposing opening M2 in the lower surface thereof. Specifically, the second divided case 22 is formed in such a shallow tray shape that a rectangular peripheral wall 22B suspends from a peripheral edge portion of a top wall 22A. The top wall 22A is formed in a quadrangular flat plate shape. The rectangular peripheral wall 22B is formed in a rectangular tubular shape, and extends downward of the top wall 22A. As indicated by a dash-dot-dot line (virtual line) in FIG. 5, the board opposing opening M2 is a substantially quadrangular opening defined by the lower edge of the rectangular peripheral wall 22B, and in bottom view, the entirety of the top wall 22A is exposed therethrough. The board opposing opening M2 is formed with the substantially same size as that of the board passing opening M1. Precisely, the board opposing opening M2 is formed, in bottom view, with a size obtained by excluding a rear portion of a later-described tube top wall 32A from the top wall 22A. Note that the lower surface of the second divided case 22 may be taken as the lower surface of the second divided case 22 in a case where it is assumed that there is no board opposing opening M2.

Two pairs of engagement hooks 25 (four engagement hooks 25) are provided apart from each other in the front-rear direction on both left and right side surfaces (outer surfaces) of the rectangular peripheral wall 22B of the second divided case 22. Moreover, one engagement hook 25 is provided on the outer surface of the rectangular peripheral wall 22B. The five engagement hooks 25 in total are provided corresponding to the five engagement claws 24 of the first divided case 21. Each engagement hook 25 protrudes outward of the outer surface of the rectangular peripheral wall 22B, and extends downward of the lower edge of the rectangular peripheral wall 22B. Each engagement hook 25 is formed in a plate shape (fin shape) elastically deformable in the left-right direction with a portion connected to the rectangular peripheral wall 22B as the point of support. An engagement groove 26 is cut from the upper end to the vicinity of the lower end in each engagement hook 25. Although details will be described later, in a state of the second divided case 22 closing the board passing opening M1, each engagement claw 24 is fitted in the engagement groove 26 of the engagement hook 25, and a lower portion of each engagement hook 25 engages with the lower end surface of the engagement claw 24 (see FIGS. 1 and 2). In this manner, the second divided case 22 is fixed to the first divided case 21, thereby forming the case body 20.

### First Divided Tubular Portion

As shown in FIGS. 3 and 4, the first divided tubular portion 31 is formed integrally with the first divided case 21 at a center portion of the front of the rectangular peripheral wall 21B in the left-right direction. The first divided tubular portion 31 is formed in a box shape having a contact passing opening M3 continuous to the board passing opening M1 of the first divided case 21. Specifically, the first divided tubular portion 31 is formed in a deep U-shaped groove shape having a narrower width in the left-right direction than that of the first divided case 21 and extending in the front-rear direction. Moreover, a rear portion of the first divided tubular portion 31 bites into the first divided case 21, and the first divided tubular portion 31 extends outward (forward) of the inside of the first divided case 21. The contact passing opening M3 is formed in the opened upper surface of the first divided tubular portion 31.

The first divided tubular portion 31 is formed in such a U-shaped groove shape that a pair of tube side walls 31B stands on both ends of a tube bottom wall 31A in the left-right direction. The tube bottom wall 31A is formed in a rectangular flat plate shape, and at a position shifted upward from the bottom wall 21A of the first divided case 21, is formed parallel to the bottom wall 21A. A pair of engagement claws 24 is provided on the outer surfaces of the pair of tube side walls 31B provided outside the first divided case 21. A pair of first guide recesses 33 is formed so as to be recessed from the inner surfaces of upper end portions of the pair of tube side walls 31B provided outside the first divided case 21. A rear portion (inside the first divided case 21) of each tube side wall 31B is formed shorter (lower) in the up-down direction than a front portion (outside the first divided case 21). The upper end surface of the rear portion of each tube side wall 31B is coincident with the upper surface of the board fixing portion 23 (see FIG. 4). The upper end surface of the front portion of each tube side wall 31B is coincident with the upper edge of the rectangular peripheral wall 21B of the first divided case 21 (see FIG. 4).

The first divided tubular portion 31 has a tube end wall 31C coupled to the rear end of the tube bottom wall 31A and the rear ends of the pair of tube side walls 31B. That is, the front of the first divided tubular portion 31 is opened, and the rear of the first divided tubular portion 31 is closed with the tube end wall 31C. The tube end wall 31C protrudes upward of the rear end of the tube bottom wall 31A and the rear end of the bottom wall 21A, and the upper end surface of the tube end wall 31C is coincident with the upper end surface of the rear portion of each tube side wall 31B. The tube end wall 31C and the rear portions of the pair of tube side walls 31B form a first partition 34 formed in a U-shape opened forward in plan view and configured to contact the lower surface (principal surface F) of the card edge board 40. The first partition 34 is a partition wall dividing the first divided case 21 and the first divided tubular portion 31 from each other.

As indicated by a dash-dot-dot line (virtual line) in FIG. 3, the contact passing opening M3 is a quadrangular opening defined by the upper edges of the pair of tube side walls 31B and the upper edge of the tube end wall 31C, and in plan view, the entirety of the tube bottom wall 31A is exposed therethrough. Specifically, the first partition 34 (rear portion of each tube side wall 31B and tube end wall 31C) is provided lower than the front portion of each tube side wall 31B. Assuming that the first partition 34 is at the same height as that of the front portion of each tube side wall 31B, the contact passing opening M3 is an opening defined by the upper edges of the pair of tube side walls 31B and the upper edge of the tube end wall 31C. Note that part (rear portion) of the contact passing opening M3 defined by the upper edge of the first partition 34 also serves as the board passing opening M1, and therefore, may be taken as part of the board passing opening M1.

### Second Divided Tubular Portion

As shown in FIGS. 3 to 5, the second divided tubular portion 32 is formed integrally with the second divided case 22 at a center portion of the front of the rectangular peripheral wall 22B in the left-right direction. The second divided tubular portion 32 is formed in a box shape having a contact opposing opening M4. Specifically, the second divided tubular portion 32 is formed in a shallow U-shaped groove shape having a narrower width in the left-right direction than that of the second divided case 22 and extending in the front-rear direction. Moreover, a rear portion of the second divided tubular portion 32 bites into the second divided case 22, and extends outward (forward) of the inside of the second divided case 22. The contact opposing opening M4 is formed in the opened lower surface of the second divided tubular portion 32 (see FIG. 5).

The second divided tubular portion 32 is formed in such a U-shaped groove shape that a pair of tube side walls 32B suspends from both ends of the tube top wall 32A in the left-right direction. A front portion (outside the second divided case 22) of the tube top wall 32A is formed parallel to the top wall 22A at a position shifted downward from the top wall 22A of the second divided case 22. A rear portion (inside the second divided case 22) of the tube top wall 32A is formed of part of the top wall 22A of the second divided case 22. A pair of lock holes 35 is opened side by side in the left-right direction in the front portion of the tube top wall 32A. Moreover, outside the pair of lock holes 35 in the left-right direction, a pair of second guide protrusions 36 protrudes downward of the top surface of the front portion of the tube top wall 32A. The pair of engagement hooks 25 (engagement groove 26) is provided at both left and right side surfaces (outer surfaces) of the pair of tube side walls 32B provided outside the second divided case 22.

As shown in FIGS. 4 and 5, a rear portion (portion provided inside the second divided case 22) of each tube side wall 32B is formed longer (higher) in the up-down direction than a front portion (portion provided outside the second divided case 22). The lower end surface of the rear portion of each tube side wall 32B is positioned lower than the lower edge of the rectangular peripheral wall 22B of the second divided case 22 and higher than the lower end of the engagement hook 25 (see FIG. 4). The lower end surface of the front portion of each tube side wall 32B is coincident with the lower edge of the rectangular peripheral wall 22B of the second divided case 22 (see FIG. 4).

The second divided tubular portion 32 has a tube end wall 32C coupled to the rear end of the tube top wall 32A and the rear ends of the pair of tube side walls 32B. That is, the front of the second divided tubular portion 32 is opened, and the rear of the second divided tubular portion 32 is closed with the tube end wall 32C. The tube end wall 32C protrudes downward of the rear end of the tube top wall 32A (or the top wall 22A), and the lower end surface of the tube end wall 32C is coincident with the lower end surface of the rear portion of each tube side wall 32B. The tube end wall 32C and the rear portions of the pair of tube side walls 32B form a second partition 37 formed in a U-shape opened forward as viewed from the bottom and configured to contact the upper surface (principal surface F) of the card edge board 40. The second partition 37 is a partition wall dividing the second divided case 22 and the second divided tubular portion 32 from each other.

As indicated by a dash-dot-dot line (virtual line) in FIG. 5, the contact opposing opening M4 is a quadrangular opening defined by the lower edges of the pair of tube side walls 32B and the lower edge of the tube end wall 32C, and as viewed from the bottom, the entirety of the tube top wall 32A is exposed therethrough. Specifically, the front portion of each tube side wall 32B is provided higher than the rear portion (second partition 37) of each tube side wall 32B. Thus, assuming that the front portion of each tube side wall 32B is at the same height as that of the rear portion, the contact opposing opening M4 is an opening defined by the lower edges of the pair of tube side walls 32B and the lower edge of the tube end wall 32C. The contact opposing opening M4 is formed in the same shape with the same size as those of the contact passing opening M3.

### Card Edge Board

The card edge board 40 will be described with reference to FIGS. 3 and 4. The card edge board 40 is a so-called electrical board (printed circuit board), and has the board body 41 formed in a thin plate shape and contacts 42 formed on both front and back surfaces of an end portion of the board body 41.

### Board Body

In plan view, the board body 41 is formed in a quadrangular shape slightly smaller than the board passing opening M1 of the first divided case 21. In other words, the board body 41 (card edge board 40) is formed so as to pass through the board passing opening M1 in a horizontal posture (posture parallel to the upper surface or bottom wall 21A of the first divided case 21) and be housed in the first divided case 21 in the horizontal posture. Four corner portions of the board body 41 are formed with loose insertion holes 43 through which screws 45 are insertable in a thickness direction (up-down direction). Both front and back corner portions of a front edge portion (front side) of the board body 41 are diagonally chamfered. Note that although not shown in the figure, at least one of the upper surface (front surface) or lower surface (back surface) of the board body 41 is formed with an electrical circuit and a plurality of electronic components is mounted (soldered).

Note that in the present specification, a main surface of surfaces of the board body 41 (card edge board 40) formed in the thin plate shape, which has a substantially greater area than those of other surfaces, is referred to as a “principal surface F”. Since the board body 41 (card edge board 40) is in the thin plate shape, there is another surface facing one principal surface F and having a great area. That is, two principal surfaces F are on both front and back sides of the board body 41 (card edge board 40), and one of the two principal surfaces F is a front surface, and the other principal surface F is a back surface.

### Contact

The contacts 42 are formed at a center portion in the left-right direction at the front edge portion of the board body 41. The contacts 42 are part of the board body 41 including a plurality of electrode patterns 44 formed on both front and back surfaces of the board body 41. For example, four electrode patterns 44 are formed at equal intervals in the left-right direction on the front surface (upper surface) of the board body 41, and four electrode patterns 44 are also formed at equal intervals in the left-right direction on the back surface (lower surface) of the board body 41 (FIG. 3 does not show the electrode patterns 44 on the back surface). Each electrode pattern 44 is electrically connected to the electrical circuit formed on the board body 41.

### Steps of Assembling Card Edge Board Device

With reference to FIGS. 1, 3, 4, and 6, one example of steps of assembling the card edge board device 5, in other words, steps of housing the card edge board 40 in the board case 10 will be described. The card edge board device 5 is automatically assembled using a manufacturing apparatus (not shown), or is manually assembled by a worker, for example.

The first divided case 21 and the first divided tubular portion 31 are placed on a horizontal top plate of a work table in a posture (horizontal posture) of the board passing opening M1 and the contact passing opening M3 facing upward. The card edge board 40 is disposed above the first divided case 21 in the horizontal posture (posture of the principal surface F being parallel to the upper surface of the first divided case 21) (see FIGS. 3 and 4). The card edge board 40 (board body 41) moves downward while maintaining its horizontal posture, enters the first divided case 21 through the board passing opening M1, and is placed on the upper end surfaces of the four board fixing portions 23 and the upper end surface of the first partition 34. The contacts 42 move downward together with the board body 41, and enter the first divided tubular portion 31 through the contact passing opening M3. The card edge board 40 (board body 41) is fixed to the first divided case 21 by screwing each screw 45 penetrating the loose insertion hole 43 into the internal threaded hole of the board fixing portion 23 (see FIG. 6).

As described above, the first divided case 21 supports (houses) the board body 41 having passed through the board passing opening M1 in the horizontal posture (posture of the principal surface F being parallel to the upper surface which is one surface having the board passing opening M1) while maintaining the posture at the time of passage through the board passing opening M1. The first divided tubular portion 31 supports (houses) the contacts 42 having passed through the contact passing opening M3 along with passage of the board body 41 through the board passing opening M1 while maintaining the posture at the time of passage through the contact passing opening M3.

Next, the second divided case 22 and the second divided tubular portion 32 are disposed above the first divided case 21 and the first divided tubular portion 31 in a posture (horizontal posture) of the board opposing opening M2 and the contact opposing opening M4 facing down, and move downward while maintaining the horizontal posture (see FIGS. 3 and 4). Along with downward movement of the second divided case 22 and the second divided tubular portion 32, each engagement hook 25 is elastically deformed outward in the left-right direction while a lower end portion of each engagement hook 25 is contacting the engagement claw 24 (specifically, the inclined surface of the engagement claw 24), and each engagement claw 24 is fitted in the engagement groove 26 after having moved over the lower end portion of the engagement hook 25 (see FIG. 1). In this state, the second divided case 22 and the second divided tubular portion 32 are each disposed on an upper portion of the first divided case 21 and an upper portion of the first divided tubular portion 31, and are coupled to the first divided case 21 and the first divided tubular portion 31 through each engagement hook 25 engaged with the engagement claw 24. The second divided case 22 is disposed with the board body 41 sandwiched between the second divided case 22 and the first divided case 21, and closes the board passing opening M1 (see FIG. 6). The second divided tubular portion 32 is disposed with the contacts 42 sandwiched between the second divided tubular portion 32 and the first divided tubular portion 31, and closes the contact passing opening M3 (see FIG. 6).

As shown in FIG. 1, the first divided case 21 and the second divided case 22 are coupled to form the case body 20, and the first divided tubular portion 31 and the second divided tubular portion 32 are coupled to form the fitting tubular body 30. As shown in FIG. 6, the board body 41 is housed inside the case body 20 (housing space S1), and the contacts 42 are housed inside the fitting tubular body 30 (fitting space S2). The fitting tubular body 30 is formed in the rectangular tubular shape opened forward along a direction parallel to the principal surface F of the card edge board 40 and extending outward (forward) of the inside of the housing space S1. That is, the fitting tubular body 30 has, at the front thereof, the opening communicating with the fitting space S2. In this state, the second partition 37 of the second divided tubular portion 32 contacts, at the lower end surface thereof, the upper surface (principal surface F) of the board body 41, and the board body 41 is sandwiched between the second partition 37 and the first partition 34. The first partition 34 and the second partition 37 form a partition structure 15 contacting both front and back surfaces of the board body 41 to divide the housing space S1 and the fitting space S2 from each other.

As described above, the card edge board device 5 is completed.

In the card edge board device 5 (board case 10) according to the first embodiment as described above, the case body 20 is dividable into the first divided case 21 and the second divided case 22, the fitting tubular body 30 is dividable into the first divided tubular portion 31 and the second divided tubular portion 32, the first divided case 21 and the first divided tubular portion 31 are integrally formed, and the second divided case 22 and the second divided tubular portion 32 are integrally formed. Moreover, the board passing opening M1 is opened in the upper surface of the first divided case 21, and the board body 41 passes through the board passing opening M1 in the posture parallel to the upper surface (or the bottom surface) of the first divided case 21. Further, the contact passing opening M3 continuous to the board passing opening M1 is opened in the first divided tubular portion 31, and when the board body 41 passes through the board passing opening M1, the contacts 42 pass through the contact passing opening M3 and are disposed in the fitting space S2. According to this configuration, the card edge board 40 (board body 41 and contacts 42) can be housed in the first divided case 21 and the first divided tubular portion 31 while being maintained in the posture parallel to the upper surface (or the bottom surface) of the first divided case 21. With this configuration, when the card edge board 40 is housed in the board case 10, it is not necessary to incline the card edge board 40 or change the posture thereof, and the card edge board 40 can be easily housed in the board case 10. Moreover, although various electronic components are mounted on the principal surface F of the board body 41, the card edge board 40 (board body 41) is housed in the first divided case 21 while being maintained in the posture parallel to the upper surface (or the bottom surface) of the first divided case 21, and therefore, in a housing process, contact of the electronic components with the first divided case 21 is reduced. With the above-described configuration, a process of incorporating the card edge board 40 into the board case 10 can be mechanized (automated), and therefore, a cost for a process of housing the card edge board 40 in the board case 10 can be reduced.

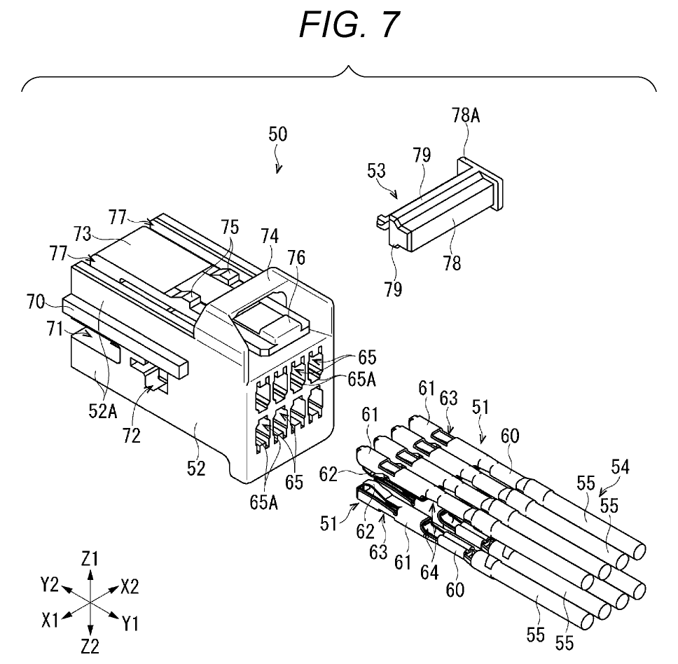

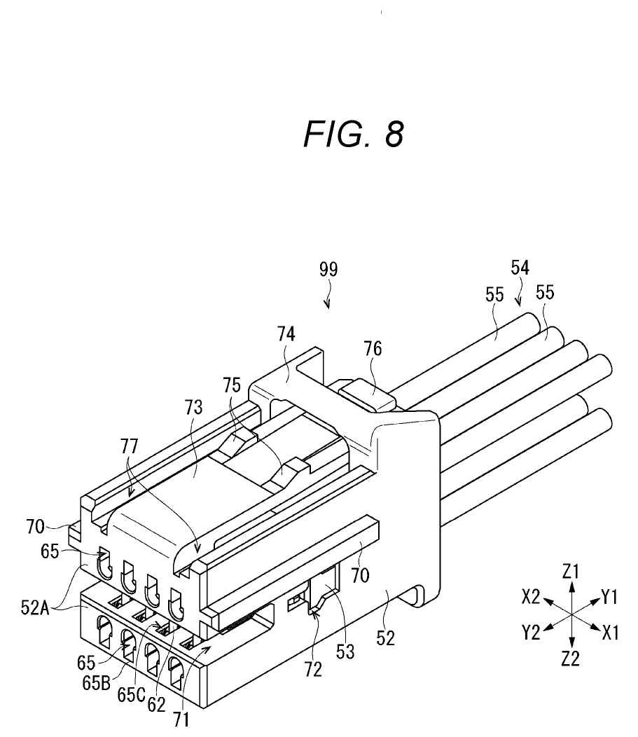

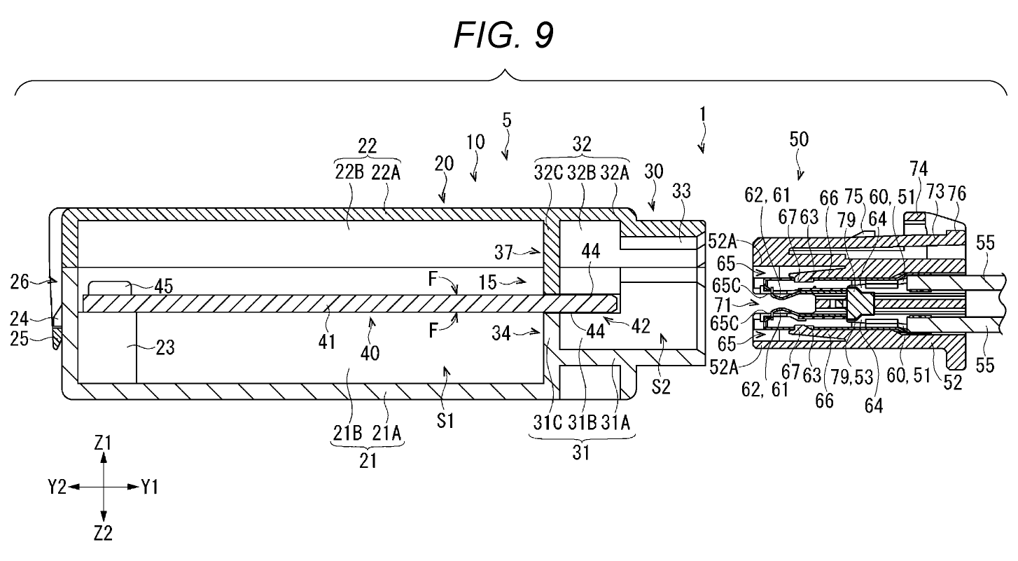

According to the card edge board device 5 (board case 10) of the first embodiment, the partition structure 15 can divide the housing space S1 and the fitting space S2 from each other, and therefore, entrance of a foreign substance into the housing space S1 (inside the case body 20) from the fitting space S2 can be reduced. Thus, the card edge board 40 (electronic components mounted on the board body 41) can be protected from the foreign substance.

[Card Edge Connector] Next, the card edge connector 50 will be described with reference to FIGS. 7 to 9. FIG. 7 is an exploded perspective view showing the card edge connector 50. FIG. 8 is a perspective view showing the card edge connector 50. FIG. 9 is a sectional view showing the card edge connection structure 1 (before connection).

As shown in FIG. 7, the card edge connector 50 includes a plurality of terminals 51 (for example, eight terminals 51), a housing 52, and a retainer 53. Note that the plurality of terminals 51 has the same structure, and for this reason, one terminal 51 will be mainly described in the present specification. Moreover, the same also applies to a plurality of components provided corresponding to the plurality of terminals 51. Note that as the terminals 51 and the components and the like provided corresponding to the terminals 51, at least one terminal 51, at least one component and the like may be provided, and the numbers of terminals 51 and components may be freely increased or decreased.

### Terminal

The eight terminals 51 are arrayed in a matrix of two rows and 4 columns in back view (or front view). That is, four terminals 51 arranged in the left-right direction are disposed as each of two lines arranged one above the other. The terminal 51 is fixed to a tip end portion (rear end portion) of a cable 55 (electrical wire). The terminal 51 is formed, for example, in such a manner that a single metal plate is punched and bent. The terminal 51 has a crimping portion 60 crimped to the tip end portion of the cable 55, and a connection portion 61 extending rearward of the crimping portion 60. The connection portion 61 is formed in a tubular shape, a terminal contact 62 bent so as to protrude outward of the tubular shape is formed on one surface of the connection portion 61 in the up-down direction, and a lock hole 63 is opened in the other surface of the connection portion 61 in the up-down direction. Moreover, a holding gap 64 is formed between the one surface of the connection portion 61 in the up-down direction and the crimping portion 60. Note that the terminals 51 in the two upper and lower lines are provided in a posture of the terminal contacts 62 thereof facing each other. Moreover, the plurality of cables 55 fixed to the plurality of terminals 51 is bundled to form the wire harness 54.

### Housing

The housing 52 is integrally molded of non-conductive synthetic resin, for example. As shown in FIGS. 7 and 8, the housing 52 is formed in a rectangular parallelepiped shape fittable in the fitting tubular body 30 of the board case 10. A pair of first guide protrusions 70 is provided on both left and right side surfaces of the housing 52. The first guide protrusion 70 is provided higher than the center of the housing 52 in the up-down direction. In the housing 52, a board entrance groove 71 is cut forward of the rear end surface (tip end surface). The board entrance groove 71 is cut to about 1/3 of the total length of the housing 52 in the front-rear direction from the rear end surface. The board entrance groove 71 is formed on the lower side of each first guide protrusion 70, and divides a rear portion of the housing 52 in half in the up-down direction. At the rear portion of the housing 52, a pair of contact housing portions 52A is formed so as to face each other with the board entrance groove 71 interposed therebetween. Although details will be described later, when the card edge connector 50 (housing 52) is fitted in the fitting tubular body 30, a front end portion (contacts 42) of the board body 41 enters the board entrance groove 71.

The housing 52 has a plurality of housing chambers 65 (for example, eight housing chambers 65), a holding attachment hole 72, a lock arm 73, and a fitting restriction portion 74.

### Housing Chamber

The eight housing chambers 65 are spaces into which the eight terminals 51 are to be inserted (housed) in an electrically-insulated state, and in front view (or back view) of the housing 52, are arranged in a matrix of 2 rows and four columns. In each contact housing portion 52A, four housing chambers 65 are formed. The housing chamber 65 is a through-hole penetrating the housing 52 in the front-rear direction. Eight insertion holes 65A (see FIG. 7) are opened in the front end surface of the housing 52, and eight communication holes 65B (see FIG. 8) are opened in the rear end surfaces of the pair of contact housing portions 52A. The terminal 51 is inserted (housed) into the housing chamber 65 through the insertion hole 65A. Eight contact holes 65C (see FIG. 8) are opened in the opposing surfaces of the pair of contact housing portions 52A sandwiching the board entrance groove 71. The terminal contact 62 of the terminal 51 housed in the housing chamber 65 is exposed to the board entrance groove 71 through the contact hole 65C (see FIGS. 8 and 9).

As shown in FIG. 9, a lance 66 protruding downward of the top surface and extending rearward is provided in the upper housing chamber 65. A lance 66 protruding upward of the bottom surface and extending rearward is provided in the lower housing chamber 65. The lance 66 is formed displaceable in the up-down direction with elastic force with a base portion (front end portion) as the point of support. A tip end portion (rear end portion) of the lance 66 is formed with a lance claw 67. The lance claw 67 engages with the lock hole 63 of the terminal 51 housed in the housing chamber 65.

### Holding Attachment Hole

As shown in FIGS. 7 and 8, the holding attachment hole 72 is formed in the vicinity of the center of the housing 52 in the front-rear direction in order to attach the later-described retainer 53. The holding attachment hole 72 is a through-hole penetrating the housing 52 in the left-right direction. In the top surface and bottom surface forming the holding attachment hole 72, holding holes 72A communicating with the eight housing chambers 65 are opened.

### Lock Arm

The lock arm 73 is bent forward while protruding upward of an upper portion of the rear end of the housing 52, and extends to a front end portion of the housing 52. The lock arm 73 is formed displaceable in the up-down direction with elastic force with a base portion (rear end portion) as the point of support. A pair of lock claws 75 and a disengagement portion 76 are formed on the upper surface of the lock arm 73. The pair of lock claws 75 is apart from each other in the left-right direction, and protrudes from the vicinity of the center of the lock arm 73 in the front-rear direction. The disengagement portion 76 is formed in a rectangular parallelepiped shape, and is provided at a front end portion of the lock arm 73. Note that a pair of second guide recesses 77 is formed between both side walls of the housing 52 in the left-right direction and the lock arm 73 in an upper portion of the housing 52.

### Fitting Restriction Portion

The fitting restriction portion 74 is formed in an arch shape so as to extend over a front portion of the housing 52, specifically the lock arm 73, between the lock claws 75 and the disengagement portion 76. Note that the pair of second guide recesses 77 described above is formed in rear of the fitting restriction portion 74.

### Retainer

The retainer 53 is integrally molded of non-conductive synthetic resin, for example. The retainer 53 is formed insertable (housable) into the holding attachment hole 72 of the housing 52. As shown in FIG. 7, the retainer 53 has a holding body 78 formed in a rod shape extending in the left-right direction and a pair of holding protrusions 79 protruding from both upper and lower surfaces of the holding body 78. The holding body 78 is formed in accordance with the dimension of the housing 52 in the left-right direction. A right end portion of the holding body 78 is formed with a plate-shaped flange 78A which extends in the front-rear direction.

### Steps of Assembling Card Edge Connector

Next, one example of steps of assembling the card edge connector 50 will be described with reference to FIGS. 7 to 9.

The terminal 51 is crimped to the tip end portion of the cable 55, and is inserted into the housing chamber 65 through the insertion hole 65A opened in the front end surface of the housing 52. A tip end portion of the connection portion 61 of the terminal 51 contacts the lance claw 67, and the terminal 51 is inserted while elastically deforming the lance 66. Along with insertion of the terminal 51, the lance claw 67 relatively moves forward while contacting the connection portion 61, and is fitted in the lock hole 63 of the connection portion 61 (see FIG. 9). In this state, the terminal contact 62 of the terminal 51 protrudes to the board entrance groove 71 from the contact hole 65C of the contact housing portion 52A (see FIGS. 8 and 9). Moreover, the tip end (rear end) of the connection portion 61 of the terminal 51 contacts an edge portion of the communication hole 65B, and the holding gap 64 of the connection portion 61 faces the holding hole 72A of the housing 52 (holding attachment hole 72) (see FIG. 9).

The retainer 53 is inserted leftward into the holding attachment hole 72 from the right, and is housed inside the holding attachment hole 72. When the retainer 53 is housed in the holding attachment hole 72, the pair of holding protrusions 79 of the retainer 53 protrudes into each housing chamber 65 from the holding hole 72A of the housing 52, and is fitted in the holding gap 64 of the terminal 51 housed in each housing chamber 65 (see FIG. 9). Since the holding protrusion 79 contacts the rear end of the connection portion 61, extraction of the terminal 51 housed in the housing chamber 65 is restricted. Note that when the retainer 53 is housed in the holding attachment hole 72, the flange 78A of the retainer 53 forms the same plane as that of the right side surface of the housing 52 (not shown).

As described above, the card edge connector 50 is completely assembled.

### Connection between Card Edge Board Device and Card Edge Connector

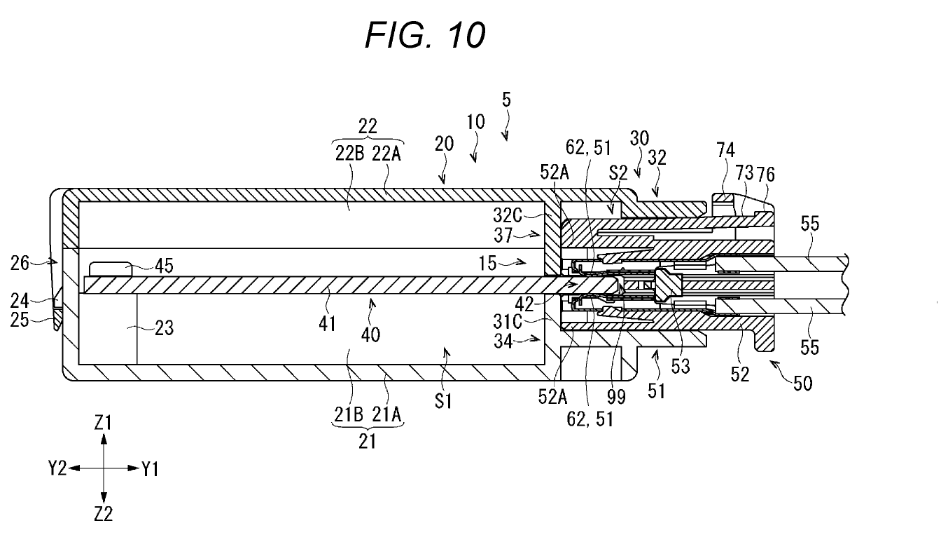

Next, with reference to FIGS. 1, 2, 9, and 10, one example of steps of connecting the card edge connector 50 to the card edge board device 5 will be described. FIG. 10 is a sectional view showing the card edge connection structure 1 (after connection).

The card edge connector 50 is inserted into the fitting tubular body 30 (fitting space S2) of the board case 10 from the front opening thereof. When the card edge connector 50 is inserted into the fitting tubular body 30, the pair of first guide protrusions 70 provided at the housing 52 enters the pair of first guide recesses 33 provided in the fitting tubular body 30, and the pair of second guide protrusions 36 provided at the fitting tubular body 30 enters the pair of second guide recesses 77 provided in the housing 52. The card edge connector 50 is inserted into the fitting tubular body 30 while being guided by the first guide protrusions 70 and the second guide protrusions 36 each having entered the first guide recesses 33 and the second guide recesses 77.

When insertion of the card edge connector 50 progresses, the pair of lock claws 75 contacts the front end of the tube top wall 32A of the fitting tubular body 30, and the card edge connector 50 is inserted while elastically deforming the lock arm 73 downward. Each lock claw 75 moves rearward while contacting the tube top wall 32A, and is fitted in the lock hole 35. In this manner, removal of the card edge connector 50 fitted in the fitting tubular body 30 is restricted.

When insertion of the card edge connector 50 further progresses, the front end portion (contacts 42) of the board body 41 relatively enters the board entrance groove 71 of the housing 52, and contacts the plurality of terminal contacts 62 protruding to the board entrance groove 71 from the opposing surfaces of the pair of contact housing portions 52A. When insertion of the card edge connector 50 further progresses, the contacts 42 of the board body 41 enter between the terminal contacts 62 facing each other in the up-down direction while opening, in the up-down direction, the terminal contacts 62 facing each other in the up-down direction in the card edge connector 50. The terminal contacts 62 facing each other in the up-down direction sandwich the front end portion (contacts 42) of the board body 41 having entered the board entrance groove 71, and contact the contacts 42 (electrode patterns 44) provided on both front and back surfaces of the end portion of the board body 41 (see FIG. 10). Each terminal contact 62 contacts the electrode patterns 44 of the contact 42 with elastic force.

As described above, the card edge connector 50 is fitted in the fitting tubular body 30, and the card edge connector 50 is connected to the card edge board device 5 (card edge board 40). In this state, the tip end surface (rear end surface) of each contact housing portion 52A abuts the front of the tube end walls 31C, 32C of the partition structure 15 (or faces such tube end walls with a slight gap therebetween). The fitting restriction portion 74 (specifically, the rear surface of the fitting restriction portion 74) faces a front end portion of the tube top wall 32A of the fitting tubular body 30 with a slight gap therebetween. With this configuration, insertion of the card edge connector 50 into the fitting tubular body 30 is restricted. Note that in a case where the card edge connector 50 is pulled out of the fitting tubular body 30, the lock arm 73 may be bent downward by pressing down the disengagement portion 76 and the card edge connector 50 may be pulled out while each lock claw 75 is separated from the lock hole 35.

In a case where an electronic board device such as the card edge board device 5 is manufactured, a partner housing in which the card edge connector 50 is to be fitted may be disposed on the board body 41 so as to surround the contacts 42, and may be fixed to the board body 41 by soldering or the like (not shown). In this case, the partner housing needs to be prepared and soldered, which takes extra time and effort for manufacturing the electronic board device and increases a manufacturing cost. On the other hand, in the card edge connection structure 1 (card edge board device 5) according to the first embodiment, the first divided tubular portion 31 and the second divided tubular portion 32 are combined to form the fitting tubular body 30, and the fitting tubular body 30 functions as the quasi-partner housing which houses the contacts 42. According to this configuration, a process of fixing the partner housing to the board body 41 can be omitted, and therefore, the card edge board device 5 can be easily manufactured at a low cost.

### Modification of First Embodiment

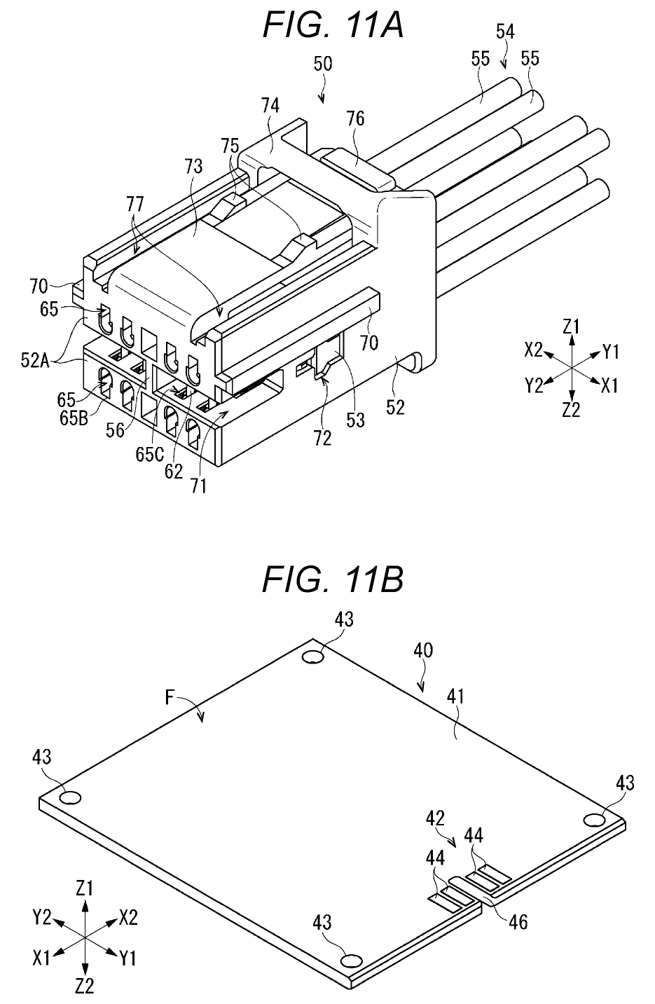

Next, a modification of the first embodiment will be described with reference to FIGS. 11A and 11B. FIG. 11A is a perspective view showing the card edge connector 50. FIG. 11B is a perspective view showing the card edge board 40.

As shown in FIG. 11A, in the modification of the first embodiment, the housing 52 of the card edge connector 50 has a rib 56 bridged between the pair of contact housing portions 52A. The rib 56 is provided in a standing posture at the center of the board entrance groove 71 in the left-right direction, and couples the pair of contact housing portions 52A. The board entrance groove 71 is divided in half in the left-right direction by the rib 56.

As shown in FIG. 11B, in the modification of the first embodiment, a cutout 46 is formed in the front end portion of the board body 41. The cutout 46 is recessed rearward of the front end at the center of the board body 41 in the left-right direction. The contacts 42 are divided in half in the left-right direction by the cutout 46. The rib 56 is fitted in the cutout 46 when the card edge connector 50 is fitted in the fitting tubular body 30.

According to the card edge connection structure 1 of the modification of the first embodiment, the rib 56 couples the pair of contact housing portions 52A. Thus, separation or approaching of the pair of contact housing portions 52A can be reduced, and the pair of contact housing portions 52A can be maintained with a predetermined interval. With this configuration, the internal between the plurality of terminals 51 housed in the pair of contact housing portions 52A is also constant, and therefore, the terminals 51 (terminal contacts 62) can contact the contacts 42 on both front and back surfaces of the card edge board 40 with proper pressure. When the card edge connector 50 is fitted in the fitting tubular body 30, the rib 56 is fitted in the cutout 46, and therefore, vibration of the card edge connector 50 along the left-right direction (direction parallel to the principal surface F of the card edge board 40) can be reduced. Since the pair of contact housing portions 52A is coupled by the rib 56, the stiffness of the entirety of the housing 52 is improved, and therefore, vibration of the card edge connector 50 along the up-down direction (direction perpendicular to the principal surface F of the card edge board 40) in a state of the end portion (contacts 42) of the card edge board 40 being sandwiched by the board entrance groove 71 can also be reduced.

Note that in the modification of the first embodiment above, the one rib 56 is bridged between the pair of contact housing portions 52A at the center in the left-right direction, but the present disclosure is not limited thereto. The number of ribs 56 and the position thereof may be freely changed. In this case, the number of cutouts 46 of the board body 41 and the position thereof may also be changed in accordance with the number of ribs 56 and the position thereof.

### Other Embodiments

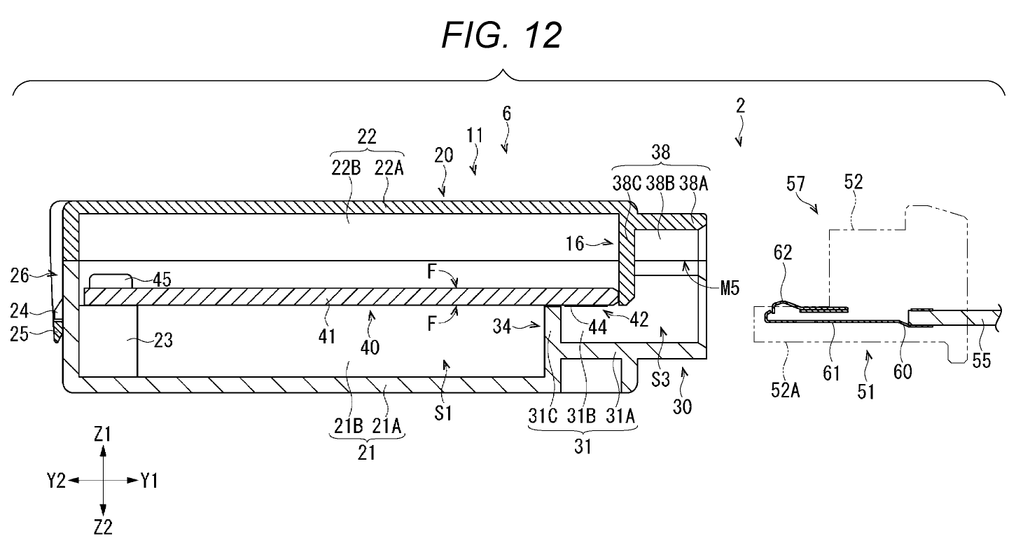

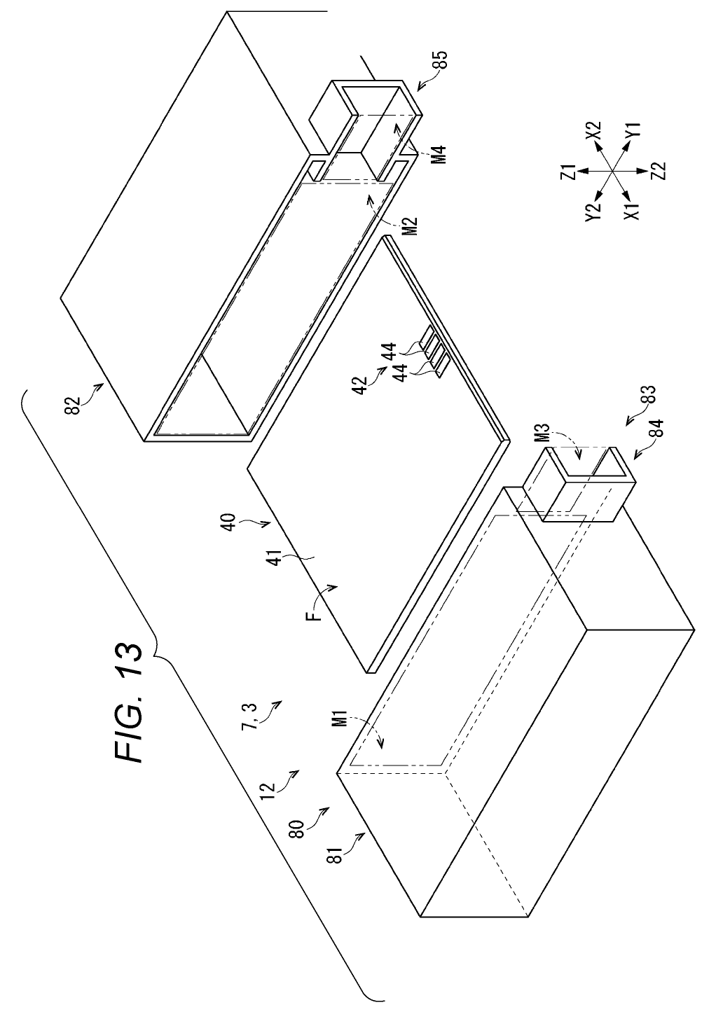

Next, other embodiments will be described with reference to FIGS. 12 and 13. FIG. 12 is a sectional view showing a card edge connection structure 2 (before connection) according to a second embodiment. FIG. 13 is an exploded perspective view schematically showing a card edge board device 7 of a card edge connection structure 3 according to a third embodiment. Note that in the following description, the same reference numerals are used to represent components similar to those of the board case 10, the card edge board device 5, and the card edge connection structure 1 (card edge connector 50) according to the above-described first embodiment including the modification, and similar description thereof may be omitted.

### Second Embodiment

As shown in FIG. 12, in the card edge connection structure 2 (card edge board device 6) according to the second embodiment, the contact 42 of the card edge board 40 is formed only on the lower surface of the front end portion of the board body 41.

In a board case 11, a second divided tubular portion 38 does not bite into the second divided case 22, and is formed in a U-shaped groove shape extending outward (forward) of the front end surface of the second divided case 22. The second divided tubular portion 38 has a pair of tube side walls 38B suspending from both ends of a tube top wall 38A in the left-right direction, and a second partition 38C coupled to the rear end of the tube top wall 38A and the rear ends of the pair of tube side walls 38B. The second partition 38C is part (center portion in the left-right direction) of a front wall of the second divided case 22 (rectangular peripheral wall 22B), and extends downward of the front end wall of the rectangular peripheral wall 22B. The lower end of the second partition 38C and the upper end of the tube end wall 31C (first partition 34) are at the same height. A corner portion of the front of the second partition 38C is diagonally chamfered. In bottom view, a contact opposing opening M5 is opened in front of the board opposing opening M2 with respect to the second partition 38C.

The card edge board 40 (board body 41) is housed in the first divided case 21 through the board passing opening M1 while maintaining its horizontal posture, the contact 42 is disposed on the first divided tubular portion 31 through the contact passing opening M3, and the second divided case 22 and the second divided tubular portion 38 close the board passing opening M1 and the contact passing opening M3. The board body 41 is housed inside the case body 20 (housing space S1), and the contact 42 is housed inside the fitting tubular body 30 (fitting space S3).

In this state, the upper end surface of the first partition 34 of the first divided tubular portion 31 contacts the lower surface (one principal surface F of the board body 41 on the first divided tubular portion 31 side) of the board body 41. The lower end of the second partition 38C of the second divided tubular portion 38 is apart upward from the tube bottom wall 31A, and the rear surface of a lower portion of the second partition 38C contacts the front end surface (end surface facing the opening of the fitting tubular body 30) of the board body 41 (contact 42). The first partition 34 and the second partition 38C form a partition structure 16 dividing the housing space S1 and the fitting space S3 from each other. Note that the fitting space S3 is a space bent in an L shape in side view. The contact 42 formed on the lower surface of the board body 41 is exposed in the fitting space S3, and the upper surface of the board body 41 is exposed in the housing space S1.

According to the card edge board device 6 (board case 11) of the second embodiment, the partition structure 16 can divide the housing space S1 and the fitting space S3 from each other, and therefore, entrance of a foreign substance into the housing space S1 (inside the case body 20) from the fitting space S3 can be reduced. Thus, the card edge board 40 can be protected from the foreign substance.

In the card edge connection structure 2 according to the second embodiment, a card edge connector 57 is formed in a shape fittable in the fitting tubular body 30 (fitting space S3) of the board case 11. Specifically, four terminals 51 (cables 55) are arranged in line in the left-right direction, and the housing chambers 65 housing the four terminals 51 are arranged in the left-right direction in a lower portion of the housing 52. The contact housing portion 52A is formed only on the lower side of the rear portion of the housing 52. Each terminal 51 is housed in the housing chamber 65 in a state of the terminal contact 62 facing up. When the card edge connector 57 is fitted in the fitting tubular body 30 (fitting space S3), the terminal contact 62 of each terminal 51 contacts the contact 42 of the card edge board 40 from below.

According to the card edge connection structure 2 (card edge board device 6) of the second embodiment, the fitting tubular body 30 functions as a quasi-partner housing which houses the contact 42. Thus, a process of fixing the partner housing to the board body 41 can be omitted, and the card edge board device 6 can be easily manufactured at a low cost.

### Third Embodiment

As shown in FIG. 13, in the card edge connection structure 3 (card edge board device 7) according to the third embodiment, a board case 12 (case body 80 and fitting tubular body 83) is dividable in the left-right direction (X1X2 direction). The case body 80 is formed dividable into a first divided case 81 and a second divided case 82. The fitting tubular body 30 is formed dividable into a first divided tubular portion 84 integrated with the first divided case 81 and a second divided tubular portion 85 integrated with the second divided case 82.

The first divided case 81 is formed in a box shape including one surface with the board passing opening M1. In the present embodiment, the board passing opening M1 is provided in the left surface of the first divided case 21.

The first divided case 81 supports (houses) the board body 41 having passed through the board passing opening M1 in the horizontal posture (posture of the principal surface F being perpendicular to the left surface which is the one surface with the board passing opening M1) while maintaining the posture at the time of passage through the board passing opening M1.

The second divided case 82 is formed, for example, in a box shape having the board opposing opening M2 in the right surface, and supports (houses) the board body 41 having passed through the board opposing opening M2 in the horizontal posture (posture of the principal surface F being perpendicular to the right surface). The second divided case 82 is disposed with the board body 41 being sandwiched between the second divided case 82 and the first divided case 81, and closes the board passing opening M1.

The first divided tubular portion 84 is formed in a box shape (U-shaped groove shape) having the contact passing opening M3 continuous to the board passing opening M1, and supports (houses) the contacts 42 having passed through the contact passing opening M3 along with passage of the board body 41 through the board passing opening M1 while maintaining the posture at the time of passage through the contact passing opening M3.

The second divided tubular portion 85 is formed, for example, in a box shape (U-shaped groove shape) having the contact opposing opening M4 continuous to the board opposing opening M2, and supports (houses) the contacts 42 having passed through the contact opposing opening M4 along with passage of the board body 41 through the board opposing opening M2. Moreover, the second divided tubular portion 85 is disposed with the contacts 42 being sandwiched between the second divided tubular portion 85 and the first divided tubular portion 84, and closes the contact passing opening M3.

Note that although not shown in the figure, the case body 80 may have a structure of supporting (fixing) the board body 41, and the fitting tubular body 30 may be provided with the partition structure 15.

According to the board case 12 of the third embodiment, effects similar to those of the board case 10 according to the first embodiment, such as an effect of easily housing the card edge board 40, can be obtained. Note that the features of the board case 12 according to the third embodiment may be applied to the board case 10, 11 according to the first or second embodiment described above (not shown).

For example, in the present disclosure, the board passing opening M1 is formed such that when the card edge board 40 is housed in the board case, the board body 41 can pass through the board passing opening M1 in a posture of the principal surface F being parallel or perpendicular to the one surface having the board passing opening M1. The board body 41 is supported by the first divided case while maintaining any one of the above-described postures at the time of passage through the board passing opening M1. Moreover, the contact passing opening M3 is formed such that when the card edge board 40 is housed in the board case, the contact 42 can pass through the contact passing opening M3 in the same posture as that of the board body 41 along with passage of the board body 41 through the board passing opening M1. The contact 42 is supported by the first divided tubular portion while maintaining the posture at the time of passage through the contact passing opening M3.

Note that each of the board cases 10 to 12 according to the first to third embodiments is provided with the partition structure 15, 16 dividing the housing space S1 and the fitting space S2 from each other, but the present disclosure is not limited thereto and the partition structure 15, 16 may be omitted (not shown).

In each of the board cases 10 to 12 according to the first to third embodiments, the second divided case 22 of the case body 20 is formed in the tray shape having the board opposing opening M2, and the second divided tubular portion 32 of the fitting tubular body 30 is formed in the U-shaped groove shape having the contact opposing opening M4. However, the present disclosure is not limited thereto. The second divided case 22 and the second divided tubular portion 32 are only required to close the board passing opening M1 of the first divided case 21 and the contact passing opening M3 of the first divided tubular portion 31, and for example, the second divided case 22 and the second divided tubular portion 32 may be formed in a flat plate shape (not shown).

Note that the embodiments above only describe one aspect of the board case, the card edge board device, and the card edge connection structure according to the present disclosure and the technical scope of the present disclosure is not limited to the embodiments above. The components in the embodiments above may be replaced or combined with existing components or the like as necessary, and the description of the embodiments above does not limit the contents of the disclosure described in the claims.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A board case for housing a card edge board having a contact at an end portion of a board body, comprising:
a case body forming a housing space in which the board body is housable; and
a fitting tubular body forming a fitting space in which the contact of the card edge board is housable and a card edge connector connected to the card edge board is fittable,
wherein the fitting tubular body is formed in a tubular shape having an opening opened along a direction parallel to a principal surface of the card edge board housed in the board case and extending outward of an inside of the housing space,
the case body is formed dividable into a first divided case and a second divided case,
the fitting tubular body is formed dividable into a first divided tubular portion formed integrally with the first divided case and a second divided tubular portion formed integrally with the second divided case,
the first divided case is formed in a box shape including one surface having a board passing opening, the board passing opening is formed such that when the card edge board is housed in the board case, the board body is able to pass through the board passing opening in a posture of the principal surface being parallel to the one surface or a posture of the principal surface being perpendicular to the one surface, and the board body is supported by the first divided case while maintaining any one of the postures at a time of passage through the board passing opening,
the second divided case is disposed with the board body being sandwiched between the second divided case and the first divided case, and closes the board passing opening,
the first divided tubular portion is formed in a box shape having a contact passing opening continuous to the board passing opening, the contact passing opening is formed such that the contact is able to pass through the contact passing opening along with passage of the board body through the board passing opening, and the contact is supported by the first divided tubular portion while maintaining a posture at a time of passage through the contact passing opening, and
the second divided tubular portion is disposed with the contact being sandwiched between the second divided tubular portion and the first divided tubular portion, and closes the contact passing opening.

2. The board case according to claim 1, wherein
the fitting tubular body has a partition structure dividing the housing space and the fitting space from each other, and the partition structure is configured to contact both front and back surfaces of the board body.

3. The board case according to claim 1, wherein
the fitting tubular body has a partition structure dividing the housing space and the fitting space from each other, and the partition structure is configured to contact the principal surface of the board body on a first divided tubular portion side and an end surface of the board body facing the opening of the fitting tubular body.

4. A card edge board device comprising:
the board case according to claim 1; and
the card edge board housed in the board case.

5. A card edge connection structure comprising:
the card edge board device according to claim 4; and
the card edge connector connected to the card edge board.

6. The card edge connection structure according to claim 5, wherein
the card edge board has the contact on both front and back surfaces of the end portion of the board body,
the card edge connector has a housing including a pair of contact housing portions and a board entrance groove, and a plurality of terminals,
the board entrance groove is configured such that when the card edge connector is fitted in the fitting tubular body, the end portion of the board body enters the board entrance groove, and the pair of contact housing portions faces each other with the board entrance groove therebetween,
the plurality of terminals is housed in the housing, sandwiches the end portion having entered the board entrance groove, and contacts the contact provided on the both front and back surfaces of the end portion of the board body,
the housing has a rib bridged between the pair of contact housing portions, and
the end portion of the board body is formed with a cutout in which the rib is fitted when the card edge connector is fitted in the fitting tubular body.
